(19) United States
(12) Patent Application Publication
(10) Pub. No.: US 2012/0194988 A1
(43) Pub. Date: Aug. 2, 2012

(54) Mobile Platform Structure Able to Vary Viewing Focal Length

(76) Inventor: Tu-Cheng Pan, Taichung City (TW)

(21) Appl. No.: 13/018,151

(22) Filed: Jan. 31, 2011

(51) Int. Cl. H05K 7/00

(52) U.S. Cl. 361/679.26

(57) ABSTRACT

A mobile platform structure able to vary a viewing focal length comprises a mobile platform, a base, a slide rail, a tooth bar, a motor, a transmission gear, a control module, a signal cable, a telemeter, and a power cord. The platform is coupled to the base via the slide rail, equipped with the tooth bar, and moved back and forth by the motor and transmission gear. The control module controls the motor to move the platform at a specified timing by a specified distance, whereby the viewing focal length of the user, who watches the display on the platform, can vary frequently lest the eyes fatigue. The telemeter is installed on the platform and detects the distance to the user's face. If the user's face approaches the platform too much, the control module controls the motor to move the platform to have an appropriate distance to the user's face.

### BACKGROUND OF THE INVENTION

1. Field of the Invention

The present invention relates to a mobile platform structure able to vary viewing focal length, carrying a display or a notebook computer, measuring the distance between the user's face and the platform when the user is watching the display on the platform, and moving the platform to an appropriate position according to the setting stored in the control module when the user's face approaches the display too much, whereby to prevent from ocular fatigue caused by overusing the eyes.

2. Description of the Related Art

When the user has watched a display or a notebook computer for a long time, or when the user watches the display at a distance too long or too short, the user's eyes are likely to fatigue. However, there is none effective measure to solve the abovementioned problem.

### SUMMARY OF THE INVENTION

Accordingly, the present invention proposes a mobile platform structure able to vary a viewing focal length, which comprises a mobile platform, a base, a slide rail, a tooth bar, a motor, a transmission gear, a control module, a signal cable, a telemeter, and a power cord. The mobile platform is movably coupled to the base via the slide rail and able to move back and forth. The mobile platform is equipped with the tooth bar and actuated to move by the motor and transmission gear arranged on the base. The control module controls the motor to move the platform at a specified timing by a specified distance according to the setting stored in the control module, whereby the viewing focal length of the user, who watches the display on the platform, can vary frequently lest the eyes fatigue. The telemeter is installed on the mobile platform and used to detect the distance between the user's face and the platform. If the user's face approaches the platform too much, the control module controls the motor to move the platform to have an appropriate distance to the user's face. The platform structure can be arranged on a desktop 12, integrated with a table, or installed on the baseplate of a display rack. As describe above, the present invention possesses utility, novelty and non-obviousness.

### BRIEF DESCRIPTION OF THE DRAWINGS

FIG. 1 is a perspective view schematically showing a mobile platform structure according to one embodiment of the present invention; and

FIG. 2 is a perspective view schematically showing the application a mobile platform structure according to one embodiment of the present invention.

### DETAILED DESCRIPTION OF THE INVENTION

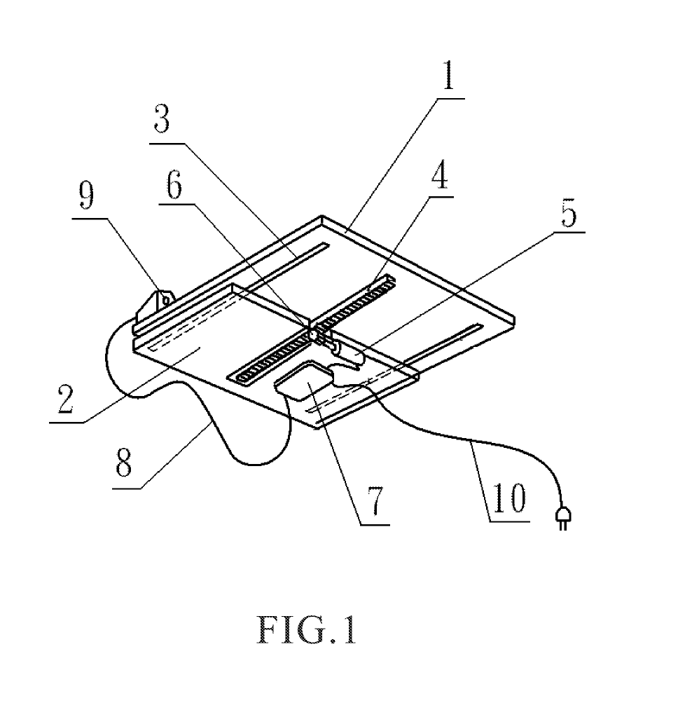

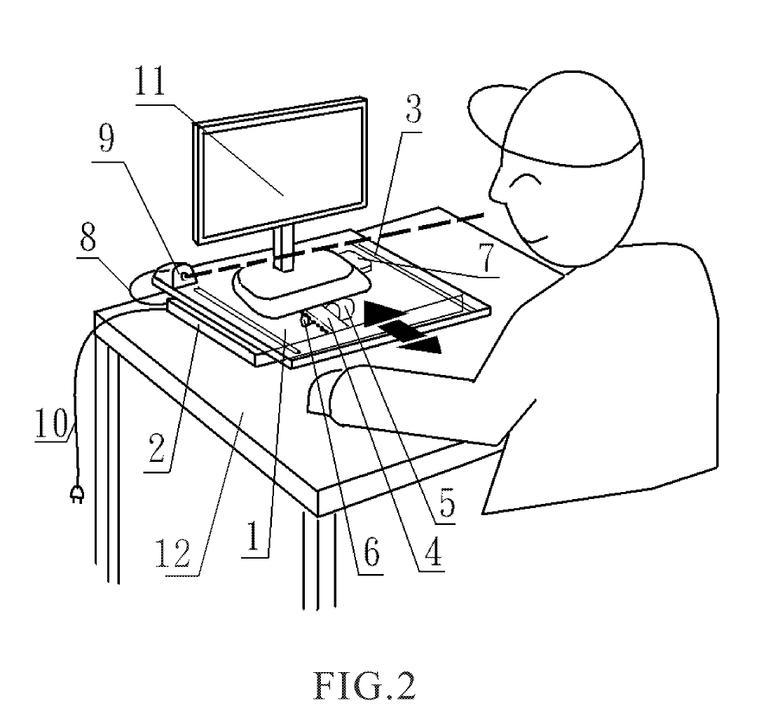

Refer to FIG. 1 and FIG. 2. The present invention proposes a mobile platform structure able to vary a viewing focal length, which comprises a mobile platform 1, a base 2, a slide rail 3, a tooth bar 4, a motor 5, a transmission gear 6, a control module 7, a signal cable 8, a telemeter 9, and a power cord 10.

The mobile platform 1 is coupled to the base 2 via the slide rail 3. The mobile platform 1 is equipped with the tooth bar 4; the motor 5 and the transmission gear 6 actuate the tooth bar 4 to move the mobile platform 1 back and forth. The motor 5, control module 7, and transmission gear 6 are arranged on the base 2. The slide rail 3 couples the mobile platform 1 and the base 2 and guides the movement of the mobile platform 1. The tooth bar 4 is arranged on the mobile platform 1 and actuated by the transmission gear 6. The motor 5 has the transmission gear 6 on the axle thereof and drives the transmission gear 6 to actuate the tooth bar 4 according to the setting stored in the control module 7. The transmission gear 6 is driven by the motor 5 to actuate the tooth gear 4. The control module 7 controls the motor 5 to rotate back and forth at programmed timings. The signal cable 8 connects with the telemeter 9 and the control module 7. The telemeter 9 detects the distance between the user's face and the mobile platform 1. According to the detected distance, the control module 7 determines whether to control the motor 5 to move the mobile platform 1. The power cord 10 supplies power to the mobile platform structure.

From the above description, it is known: the mobile platform 1 is movably coupled to the base 2 via the slide rail 3 and thus can move back and forth; the tooth bar 4 is arranged on the mobile platform 1 and can be actuated by the motor 5 and transmission gear 6 arranged on the base 2; the control module 7 controls the motor 5 to move the mobile platform 1 at a specified timing by a specified distance according to the setting stored in the control module 7; thereby can be varied the viewing focal length of the eyes of the use watching the display 11 on the mobile platform 1, lest the user's eyes fatigue; the telemeter 9 detects the distance between the mobile platform 1 and the user's face; if the user's face approaches the mobile platform 1 too much, the control module 7 controls the motor 5 to move the mobile platform 1 to maintain an appropriate distance between the mobile platform 1 and the user's face.

The embodiments described above are only to exemplify the present invention but not to limit the scope of the present invention. Any equivalent modification or variation according to the claims and specification of the present invention is to be also included within the scope of the present invention.

What is claimed is:

1. A mobile platform structure able to vary a viewing focal length, comprising
a mobile platform movably coupled to a base via a slide rail and having a tooth bar, wherein said tooth bar is actuated by a motor and a transmission gear to move said mobile platform back and forth;
a base equipped with said motor, a control module and said transmission gear, wherein said transmission gear can drive said mobile platform to move back and forth;
a slide rail movably coupling said mobile platform to said base to enable said mobile platform to move back and forth;
a tooth bar arranged on said mobile platform and actuated by said transmission gear on said base;
a transmission gear driven by said motor to actuate said tooth bar;
a control module controlling said motor to drive said mobile platform to move back and forth at a programmed timing;
a signal cable connecting with a telemeter and said control module;
a telemeter detecting a distance between said mobile platform and a user's face, wherein said control module determines according to said distance whether to control said motor to move said mobile platform and maintain an appropriate distance between said mobile platform and said user's face; and
a power cord supplying power.

2. The mobile platform structure able to vary a viewing focal length according to claim 1, wherein said base is integrated with a desktop.

3. The mobile platform structure able to vary a viewing focal length according to claim 1, wherein said mobile platform is integrated with a display.

4. The mobile platform structure able to vary a viewing focal length according to claim 1, wherein distance by which said control module controls said motor to move can be arbitrarily programmed.
